(19) United States
(12) Patent Application Publication
(10) Pub. No.: US 2026/0318986 A1
(43) Pub. Date: Oct. 15, 2026

(54) METHODS AND SYSTEMS FOR MONITORING RADIATION-INDUCED AGING IN RADIATION DETECTORS

(71) Applicant: REDLEN TECHNOLOGIES, INC., Saanichton (CA)

(72) Inventors: Krzysztof INIEWSKI, Port Moody (CA); Hiroaki NAKAI, Vancouver (CA)

(21) Appl. No.: 19/463,951

(22) Filed: Jan. 29, 2026

Related U.S. Application Data
(60) Provisional application No. 63/756,410, filed on Feb. 10, 2025.

(51) Int. Cl. G01R 31/28; H10F 39/18

(52) U.S. Cl. CPC G01R 31/2829; H10F 39/1892; H10F 39/1895

(57) ABSTRACT

Methods and systems for monitoring radiation-induced aging of application specific integrated circuits (ASICs) used in the read-out circuitry of radiation detectors are provided. An output reference signal that is dependent on the threshold voltages of transistors within the ASICs may be periodically measured. The measured output reference signals may be analyzed to determine when individual ASICs of the radiation detector need to be replaced due to excessive radiation damage. In some embodiments, the output reference signal may be a direct current (DC) voltage signal that is generated by a bandgap reference circuit of the ASIC. A maintenance process to replace an ASIC may be initiated when the measured DC voltage signal for the ASIC is below a pre-determined maintenance threshold.

### FIELD

The present disclosure relates generally to radiation detectors, and more specifically to methods and systems for monitoring radiation-induced aging in radiation detectors.

### BACKGROUND

Room temperature pixelated radiation detectors made of semiconductors, such as cadmium zinc telluride (Cd₁₋ₓZnₓTe where 0<x<1, or “CZT”), are gaining popularity for use in medical and non-medical imaging. These applications use the high energy resolution and sensitivity of the radiation detectors.

### SUMMARY

According to an aspect of the present disclosure, a method of monitoring radiation-induced aging of an application specific integrated circuit (ASIC) used in the read-out circuitry of a radiation detector structure includes measuring an output reference signal from the ASIC, where the output reference signal is dependent on threshold voltages of transistors within the ASIC, and analyzing the measured output reference signal to determine whether the ASIC needs to be replaced due to excessive radiation damage.

Further embodiments include a detector module including a radiation sensor, an ASIC electrically coupled to the radiation sensor and including signal processing circuitry configured to generate detection signals in response to photon detection events occurring within the radiation sensor, the ASIC further comprising a monitoring circuit configured to generate an output reference signal that is dependent on threshold voltages of transistors within the ASIC, and a monitoring component configured to measure the output reference signal from the monitoring circuit and to store a value associated with the measured output reference signal in a memory.

Additional embodiments include X-ray imaging systems including a radiation source configured to emit an X-ray beam, and a detector array including an above-described detector module that is configured to receive the X-ray beam from the radiation source through an intervening space configured to contain an object therein.

### BRIEF DESCRIPTION OF THE DRAWINGS

FIG. 1A is a functional block diagram of an X-ray imaging system in accordance with various embodiments of the present disclosure.

FIG. 1B is a schematic illustration of an application specific integrated circuit (ASIC) configured to count X-ray photons detected in each pixel detector within a set of energy bins according to various embodiments of the present disclosure.

FIG. 2A is a rear perspective view of a detector array for a computed tomography (CT) X-ray imaging system according to various embodiments of the present disclosure.

FIG. 2B is a perspective view of a CT X-ray imaging system illustrating the orientation of the detector array with respect to an X-ray source and a patient being imaged according to various embodiments of the present disclosure.

FIG. 3A is a side cross-section view of a radiation detector unit including a radiation sensor coupled to an ASIC by an interposer disposed between the radiation sensor and the ASIC according to various embodiments of the present disclosure.

FIG. 3B is a side cross-section view of a radiation detector unit including a radiation sensor directly mounted to an ASIC including through-substrate vias according to various embodiments of the present disclosure.

FIG. 3C a side cross-section view of a radiation detector unit including a radiation sensor directly mounted to an ASIC including a peripheral input/output with wire bond connections according to various embodiments of the present disclosure.

FIG. 4 is a system block diagram schematically illustrating a detector module including a radiation-induced aging monitoring component according to various embodiments of the present disclosure.

FIG. 5 is a plot schematically illustrating ASIC reference signal values as a function of time according to various embodiments of the present disclosure.

FIG. 6 is a flow diagram illustrating a method of monitoring radiation-induced aging of ASICs used in the read-out circuitry of radiation detector structures according to various embodiments of the present disclosure.

### DETAILED DESCRIPTION

Embodiments of the present disclosure provide detector structures for detecting ionizing radiation, the various aspects of which are described herein with reference to the drawings.

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims. Any reference to claim elements in the singular, for example, using the articles “a,” “an,” or “the” is not to be construed as limiting the element to the singular. The terms “example,” “exemplary,” or any term of the like are used herein to mean serving as an example, instance, or illustration. Any implementation described herein as an “example” is not necessarily to be construed as preferred or advantageous over another implementation. The drawings are not drawn to scale. Multiple instances of an element may be duplicated where a single instance of the element is illustrated, unless absence of duplication of elements is expressly described or clearly indicated otherwise.

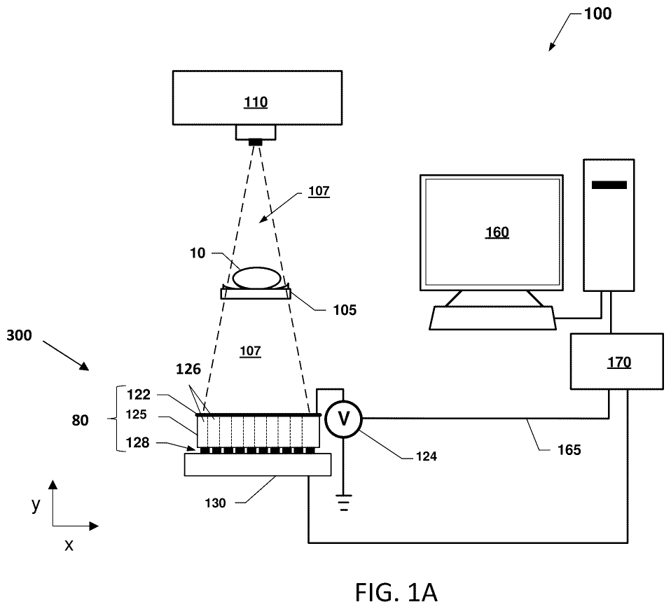

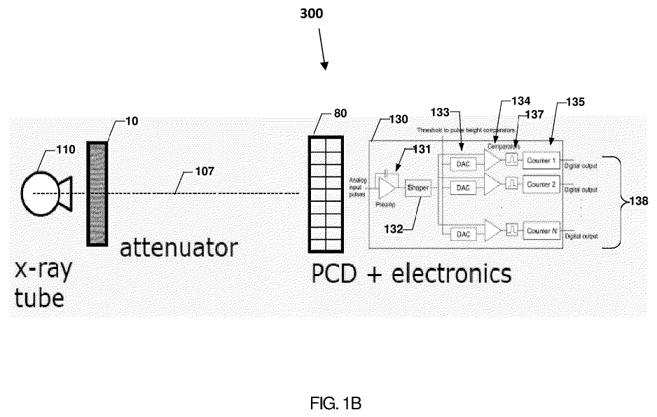

FIG. 1A is a functional block diagram of an X-ray imaging system 100 in accordance with various embodiments. The X-ray imaging system 100 may include an X-ray source 110 (i.e., a source of ionizing radiation), and an energy discriminating photon counting radiation detector array 300. The X-ray imaging system 100 may additionally include a patient support structure 105, such as a table or frame, which may rest on the floor and may support an object 10 to be scanned. In some embodiments, the object 10 may be a biologic subject (i.e., a human or animal patient). The support structure 105 may be stationary (i.e., non-moving) or may be configured to move relative to other elements of the X-ray imaging system 100, such as the X-ray source.

The X-ray source 110 is typically mounted to a gantry and may move or remain stationary relative to the object 10. The X-ray source 110 is configured to deliver ionizing radiation to the radiation detector array 300 by emitting an X-ray beam 107 toward the object 10 and the radiation detector array 300. After the X-ray beam 107 is attenuated by the object 10, the beam of radiation 107 is received by the radiation detector array 300.

The radiation detector array 300 may include one or more radiation sensors 80 coupled to detector read-out circuitry 130. Each radiation sensor 80 may be controlled by a high voltage bias power supply 124 that selectively creates an electric field between an anode 128 and cathode 122 pair coupled thereto. In one embodiment, each radiation sensor 80 includes a plurality of anodes 128 (e.g., one anode per pixel) and one common cathode 122 electrically connected to the power supply 124 and facing the X-ray source 110. Each radiation sensor 80 may include a detector material 125, such as a semiconductor material disposed between the anode 128 and cathode 122 and thus configured to be exposed to the electrical field therebetween. The semiconductor material may comprise any suitable semiconductor material for detecting X-ray radiation disposed between the anode 128 and cathode 122 and thus configured to be exposed to the electrical field therebetween. In various embodiments, the semiconductor material of the radiation sensor(s) 80 may comprise a II-VI semiconductor material, such as cadmium telluride, cadmium zinc telluride (i.e., CdZnTe or “CZT”), cadmium selenide telluride, and cadmium zinc selenide telluride. Other suitable “direct conversion” sensor materials, such as Si, Ge, GaAs, perovskites, etc., are within the contemplated scope of disclosure.

The detector read-out circuitry may include one or more application specific integrated circuits (ASICs) 130. Each ASIC 130 may be coupled to one or more radiation sensors 80 and may receive signals (e.g., charge or current) from the anodes 128 of the radiation sensor(s) 80. Each ASIC 130 may be configured to provide data to and by controlled by a control unit 170. Each of the radiation sensors 80 may be segmented or configured into a large number of small “pixel” detectors 126. In various embodiments, the pixel detectors 126 of the radiation sensors 80 and the ASIC(s) 130 are configured to output data that includes counts of photons detected in each pixel detector 126 in each of a number of energy bins. Thus, radiation detector arrays 300 of various embodiments may provide both two-dimensional detection information regarding where photons were detected, thereby providing image information, and measurements of the energy of the detected X-ray photons. A radiation detector array 300 that is capable of measuring the energy of the X-ray photons impinging on the array 300 may be referred to as an energy-discriminating radiation detector array 300.

The control unit 170 may be configured to synchronize the X-ray source 110, the read-out ASIC(s) 130, and the high voltage bias power supply 124. The control unit 170 may be coupled to and operated from a computing device 160. Alternatively, the computing device 160 and the control unit 170 may be integrated together as one device.

In some embodiments, the X-ray imaging system 100 may be a computed tomography (CT) imaging system. The CT imaging system 100 may include a gantry (not shown in FIG. 1A), which may include a moving part, such as a circular, rotating frame with the X-ray source 110 mounted on one side and the radiation detector array 300 mounted on the other side. The radiation detector array 300 may have a curved shape along its long axis (i.e., the x-axis direction in FIG. 1A) such that each of the pixel detectors 126 along the length of the radiation detector may face towards the focal spot of the X-ray source 110. The gantry may also include a stationary (i.e., non-moving) part, such as a support, legs, mounting frame, etc., which rests on the floor and supports the moving part. The X-ray source 110 may emit a fan-shaped or cone-shaped X-ray beam 107 as the X-ray source 110 and the radiation detector array 300 rotate on the moving part of the gantry around the object 10 to be scanned. After the X-ray beam 107 is attenuated by the object 10, the X-ray beam 107 is received by the radiation detector array 300. The curved shape of the radiation detector array 300 may allow the CT imaging system 100 to create a 360° continuous circular ring of the image of the object 10 by rotating the moving part of the gantry around the object 10.

For each complete rotation of the X-ray source 110 and the radiation detector array 300 around the object 10, one cross-sectional slice of the object 10 may be acquired. As the X-ray source 110 and the radiation detector array 300 continue to rotate, the radiation detector array 300 may take numerous snapshots called “views”. Typically, about 1,000 profiles are taken in one rotation of the X-ray source 110 and the radiation detector array 300. The X-ray source 110 and the detector array 300 may slowly move relative to the patient along a horizontal direction (i.e., into and out of the page in FIG. 1A) so that the detector array 300 may capture incremental cross-sectional profiles over a region of interest (ROI) of the object 10, which may include the entire object 10. The data acquired by the radiation sensor(s) 80 and output by the read-out ASIC(s) 130 may be passed along to the computing device 160 that may be located remotely from the radiation detector array 300 via a connection 165. The connection 165 may be any type of wired or wireless connection. If the connection 165 is a wired connection, the connection 165 may include a slip ring electrical connection between any structure (e.g., gantry) supporting the radiation detector array 300 and a stationary support part of the support structure, which supports any part (e.g., a rotating ring). If the connection 165 is a wireless connection, the radiation detector array 300 may contain any suitable wireless transceiver to communicate data with another wireless transceiver that is in communication with the computing device 160. The computing device 160 may include processing and imaging applications that analyze each profile obtained by the radiation detector array 300, and a full set of profiles may be compiled to form a three-dimensional computed tomographic (CT) reconstruction of the object 10 and/or two-dimensional images of cross-sectional slices of the object 10.

Various alternatives to the design of the X-ray imaging system 100 of FIG. 1A may be employed to practice embodiments of the present disclosure. X-ray imaging systems may be designed in various architectures and configurations. For example, an X-ray imaging system may have a helical architecture. In a helical X-ray imaging scanner, the X-ray source 110 and radiation detector array 300 are attached to a freely rotating gantry. During a scan, a table moves the object 10 smoothly through the scanner, or alternatively, the X-ray source 110 and detector array 300 may move along the length of the object 10, creating helical path traced out by the X-ray beam. Slip rings may be used to transfer power and/or data on and off the rotating gantry. In other embodiments, the X-ray imaging system may be a tomosynthesis X-ray imaging system. In a tomosynthesis X-ray scanner, the gantry may move in a limited rotation angle (e.g., between 15 degrees and 60 degrees) in order to detect a cross-sectional slice of the object 10. The tomosynthesis X-ray scanner may be able to acquire slices at different depths and with different thicknesses that may be reconstructed via image processing.

FIG. 1B illustrates components of an X-ray imaging system, including components within the ASIC 130 configured to count X-ray photons detected in each pixel detector 126 within a set of energy bins. As used herein, the terms “energy bin” and “bin” refer to a particular range of measured photon energies between a minimum energy threshold and a maximum energy threshold. For example, a first bin may refer to counts of photons determined to have an energy greater than a threshold energy (referred to as a trigger threshold, e.g., 20 keV) and less than 40 keV, while a second bin may refer to counts of photons determined to have an energy greater than 40 keV and less than 60 keV, and so forth.

X-rays 107 from an X-ray source (e.g., X-ray tube) 110 may be attenuated by a target (e.g., an object 10, such as a human or animal patient) before interacting with the radiation detector material within the pixelated detector array 300. An X-ray photon interacting (e.g., via the photoelectric effect) with a pixelated radiation detector material generates an electron cloud within the material that is swept by an electric field to the anode electrode 128. The charge gathered on the anode creates a signal that is integrated by an amplifier 131, such as a charge sensitive amplifier (CSA) or another amplifier, such as trans impedance amplifier (TIA). There may be an amplifier 131 for each pixel detector 126 (e.g., for each anode 128) within the pixelated X-ray detector array 300. The voltage of the amplifier output signal may be proportional to the energy of the X-ray photon. The output signal of the amplifier may be processed by an analog filter or shaper 132.

The filtered output may be connected to the inputs of a number of analog comparators 134, with each comparator connected to a digital-to-analog converter (DAC) 133 that inputs to the comparator a DAC output voltage that corresponds to the threshold level defining the limits of an energy bin. The detector circuitry 130 may be configured so that after the amplifier voltage has stabilized (after the dead time), that voltage may be between two voltage thresholds set by two DACs 133, which determines the output of the comparators 134. Outputs from the comparators 134 may be processed through decision gates 137, with a positive output from a comparator 134 corresponding to a particular energy bin (defined by the DAC output voltages) resulting in a count added to an associated counter 135 for the particular energy bin. Periodically, the counts in each energy bin counter 135 are output as signals 138 to the control unit 170.

Other suitable configurations for the read-out electronics of the ASIC 130 are within the contemplated scope of disclosure. For example, in some configurations, the analog voltage signals from the amplifier may be converted to digital signals using an analog-to-digital converter (ADC) prior to being sorted into the respective energy bins.

The detector array 300 of an X-ray imaging system may include an array of radiation detector elements, referred to herein as pixel detectors. The signals from the pixel detectors may be processed by a pixel detector circuit (e.g., an above-described ASIC 130), which may sort detected photons into energy bins based on the energy of each photon or the voltage generated by the received photon. When an X-ray photon is detected, its energy is determined and the X-ray photon count for its associated energy bin is incremented. For example, if the detected energy of an X-ray photon is 24 kilo-electron-volts (keV), the X-ray photon count for the energy bin of 20-40 keV may be incremented. The number of energy bins may be three or more, such as four to twelve. In an illustrative example, an X-ray photon counting detector may have four energy bins: a first bin for detecting photons having an energy between 20 keV and 40 keV, a second bin for detecting photons having an energy between 40 keV and 60 keV, a third bin for detecting photons having an energy between 60 keV and 90 keV, and a fourth bin for detecting photons having an energy above 90 keV (e.g., between 90 keV and 120 keV). The greater the total number of energy bins, the better the material discrimination. The total number of energy bins and the energy range of each bin may be selectable by a user, such as by adjusting the threshold levels defining the limits of the respective energy bins in the read-out ASIC 130 as shown in FIG. 1B.

In various embodiments, a detector array 300 for an X-ray imaging system 100 as described above may include a plurality of pixel detectors 126 extending over a continuous two-dimensional (2D) detector array surface. A typical radiation detector array 300 may include an array of individual radiation sensors 80 (e.g., a plate-like detector material 125 including cathode and anode electrode(s) 122, 128 defining pixel detectors 126 as described above) arranged side-by-side to provide the continuous 2D detector array surface. The detector array 300 (which is also known as a detector module system (DMS)) may further include a modular configuration including a plurality of detector modules, where each detector module may include at least one above-described radiation sensor 80, at least one ASIC 130 (also known as a read-out integrated circuit (ROIC)) electrically coupled to the at least one radiation sensor, and a module circuit board. The module circuit board may support transmission of electrical power, control signals, and data signals between the module circuit board and the at least one ASIC 130 and the at least one radiation sensor 80 of the detector module, and may further support transmission of electrical power, control signals, and data signals between the module circuit board and the control unit 170 of the X-ray imaging system 100, other module circuit boards of the detector array, and/or a power supply for the detector array. A plurality of detector modules may be assembled on a common support structure, such as a detector array frame, to form a detector array 300.

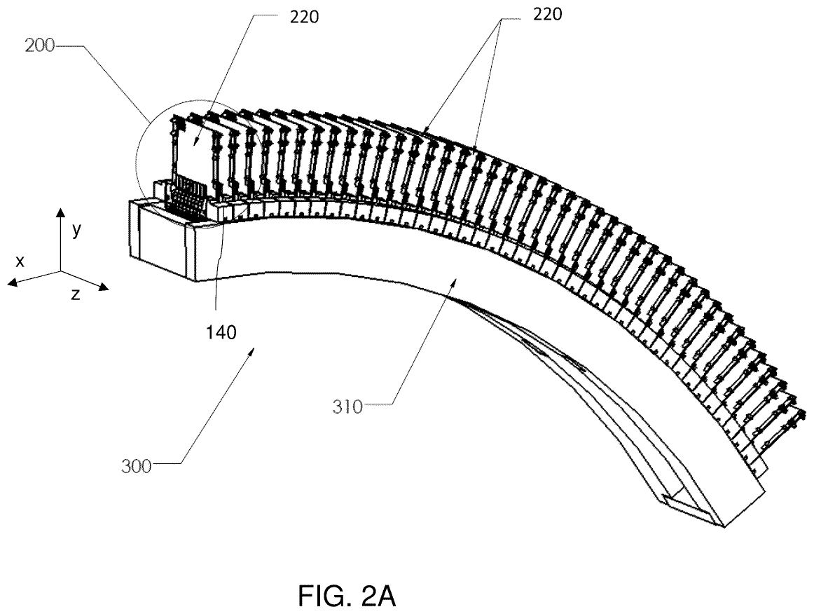

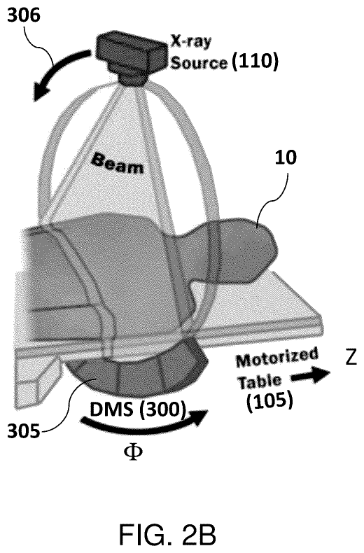

FIG. 2A is a rear perspective view of a detector array 300 for a computed tomography (CT) X-ray imaging system according to various embodiment of the present disclosure. The detector array 300 in this embodiment includes multiple detector modules 200 mounted on a detector array frame 310. The detector array frame 310 may be configured to provide attachment of a row of detector modules 200 such that physically exposed surfaces of the radiation sensors of the detector modules 200 collectively form a curved detection surface located within a cylindrical surface. The multiple detector modules 200 may be assembled such that radiation sensors attached to neighboring detector modules 200 abut each other, i.e., make direct surface contact with each other and/or include a gap between adjacent radiation sensors that is less than 3 mm, and/or less than 2 mm, and/or less than 1 mm in the x-direction. In some embodiments, the detector modules 200 may be mounted to the detector array frame 310 by attaching frame bars 90 of the detector modules 200 to the detector array frame 310 using suitable mechanical fasteners. The radiation sensors and ASICs 130 of each module 200 may be mounted over a first (i.e., front) surface of the frame bar 90. Each module 200 may also include a module circuit board 220 extending away from a rear surface of the frame bar 90. Major surfaces of the module circuit boards 220 of the detector modules 200 may face each other in the detector array 300.

FIG. 2B is a perspective view of a CT X-ray imaging system 100 illustrating the orientation of the detector array 300 with respect to an X-ray source 110 and a patient 10 being imaged according to various embodiments of the present disclosure. Referring to FIG. 2B, the X-ray source 110 and the detector array 300 (e.g., DMS) may rotate around the patient 10 and the support structure (e.g., motorized table 105) along the direction of arrow 306 to obtain cross-sectional image profiles (or “slices”) of the patient 10. The X-ray source 110 and the detector array 300 may also be translated relative to the patient 10 (e.g., by moving the support structure 105 and the patient 10 with respect to the X-ray source 110 and the detector array 300 and/or by moving the X-ray source 110 and the detector array 300 along the length of the patient 10) along a horizontal direction to obtain cross-sectional image “slices” of different portions of the patient 10. The direction of the horizontal movement of the X-ray source 110 and the detector array 300 relative to the patient 10 may be referred to as the “Z-axis” direction, which may be parallel to the axis of rotation of the X-ray source 110 and the detector array 300 around the patient 10. As discussed above, the detector array 300 may also have a curved shape along the direction in which the X-ray source 110 and the detector array 300 rotate around the patient. The pixel detectors of the detector array 300 may be arranged in multiple columns and rows of pixel detectors, where each column may extend along the Z-axis direction, and each row may extend along the direction of rotation of the detector array 300 around the patient. Accordingly, the location of each pixel detector within the detector array 300 may be defined by a unique row and column pair, where the location of the pixel detector within a given column may be defined by its location along the Z-axis direction, and the location of the pixel detector within a given row may be defined by the azimuth angle Φ of a line segment extending between the pixel detector and the focal spot of the X-ray source 110, where all pixel detectors within the same column may have the same azimuth angle Φ. The detector array 300 shown in FIG. 2B may be similar to the detector array 300 described above with reference to FIG. 2A. The detector array 300 may further include a suitable housing or enclosure 305 that encloses and protects the module circuit boards 220.

In some embodiments, each of the detector modules 200 of the detector array 300, such as the detector array 300 shown in FIGS. 2A and 2B may be constructed from a set of radiation detector units, which may also be referred to as “mini-modules” or “submodules.” In some embodiments, each radiation detector unit may include at least one radiation sensor 80 that is physically and electrically coupled to an ASIC 130 configured to read out count data from the radiation sensor(s) 80 coupled thereto. A detector module 200 may include one or more such radiation detector units mounted on a suitable support, such as an above-described frame bar 90, and may optionally include other component(s) such as an above-described module circuit board 220.

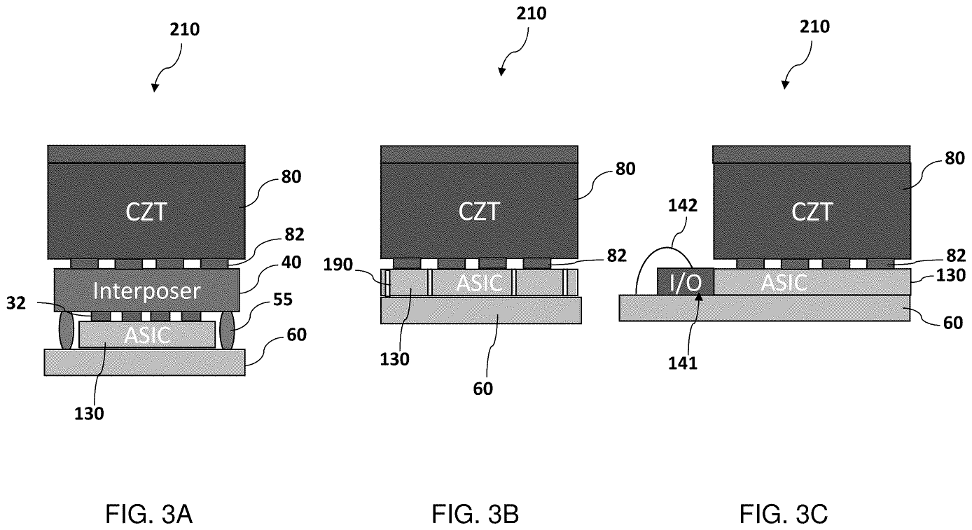

A number of different architectures may be used to integrate radiation sensors 80 with corresponding ASICs 130 to form radiation detector units. FIGS. 3A-3C are side cross-section views illustrating radiation detector units 210 having different architectures for integrating the radiation sensors 80 and ASICs 130. FIG. 3A illustrates a first radiation detector unit 210 in which one or more radiation sensors 80 is coupled to an ASIC 130 by an interposer 40 disposed between the radiation sensor(s) 80 and the ASIC 130. The embodiment of FIG. 3A includes a single radiation sensor 80 and a single ASIC 130, although it will be understood that a radiation detector unit 210 may also include multiple radiation sensors 80 and/or multiple ASICs 130. The interposer 40 may include a main body composed of one or more suitable insulating materials (e.g., semiconductor, glass, polymer (e.g., printed circuit board insulating laminate) and/or ceramic material) and conductive interconnect structures (not expressly shown in FIG. 3A) extending through and within the main body. The back side of the interposer 40 may have bonding pads that may be electrically connected to corresponding bonding pads on the front side of the ASIC 130 by first bonding structures 32, such as solder balls or copper pillars. The front side of the interposer 40 may have bonding pads that may be electrically connected to corresponding bonding pads (e.g., anode electrodes 128) on the back side of the radiation sensor 80 by second bonding structures 82, such as a low temperature solder material or conductive epoxy. As used herein, the “front side” of elements refers to the side that faces the incoming radiation, and the “backside” of elements refers to the side that is the opposite side of the front side. Detection signals from the radiation sensor 80 may be transmitted through second bonding structures 82, the conductive interconnect structures of the interposer 40, and the first bonding structures 32 to the ASIC 130. In some embodiments, the radiation sensor 80, interposer 40, and ASIC 130 may be located on a carrier board 60 (e.g., a PCB) that may handle input/output (I/O) signals for the radiation detector unit 210. The carrier board 60 may be electrically connected to the back side of the interposer 40 by third bonding structures 55, such as solder balls. Photon count data may be transmitted from the ASIC 130 to the interposer 40 and from the interposer 40 to the carrier board 60 by the third bonding structures 55. Power and control signals may be transmitted from the carrier board 60 to the interposer via the third bonding structures 55, and then from the interposer 40 to the ASIC 130. The carrier board 60, in turn, may be connected to the module circuit board 220 by a suitable connection, such as a flex cable connection (not shown in FIG. 3A). Further details and embodiments of radiation detector units 210 and detector modules 200 including an interposer 40 between one or more radiation sensors 80 and one or more ASICs 130 may be found, for example, in U.S. Pat. No. 11,067,707, which is incorporated by reference herein for all purposes.

FIG. 3B illustrates an alternative configuration of a radiation detector unit 210. In the radiation detector unit 210 of FIG. 3B, each radiation sensor 80 may be directly mounted to the front side of the ASIC 130 via a plurality of bonding structures 82, such as low temperature solder material or a conductive epoxy. In other words, each radiation sensor 80 is mechanically and electrically coupled to an ASIC 130 via the plurality of bonding structures 82, and no interposer 40 or similar intervening structural component for routing of electrical signals between the radiation sensors 80 and the ASIC 130 is located between the back side of each of the radiation sensors 80 and the front side of the ASIC 130. Such a configuration may be referred to as a “direct attach” radiation detector unit 210. Exemplary embodiments of “direct attach” radiation detector units 210 and detector modules 200 are described, for example, in U.S. Provisional Patent Application No. 63/380,769, filed on Oct. 25, 2022, and U.S. patent application Ser. No. 18/158,695, filed on Jan. 24, 2023, the entire teachings of both of which are incorporated by reference herein for all purposes.

The radiation detector unit 210 of FIG. 3B may further include a carrier board 60 as described above. The ASIC 130 may be disposed over the carrier board 60 such that the back side of the ASIC 130 may contact the front side of the carrier board 60. In some embodiments, a plurality of through-substrate vias (TSVs) 190 may be provided in the ASIC 130. The TSVs 190 may include an electrically conductive material (e.g., a metal material, such as copper) that extends between the front side and the back side of the ASIC 130. In embodiments in which the ASIC 130 may be formed on and/or in a silicon substrate, the TSVs 190 may also be referred to as “through-silicon vias.” Thus, signals between the carrier board 60 and the ASIC 130 may be transmitted through the back side of the ASIC 130. The carrier board 60 may be connected to the module circuit board 220 by a suitable connection, such as a flex cable connection, as described above.

FIG. 3C illustrates yet another example of a radiation detector unit 210 having a “direct attach” configuration. The radiation detector unit 210 of FIG. 3C may be similar to the radiation detector unit 210 of FIG. 3B in that the radiation sensor(s) 80 may be directly mounted to the front side of the ASIC 130 via a plurality of bonding structures 82. In the embodiment of FIG. 3C, the ASIC 130 may additionally include a peripheral region 141 that extends beyond the outer periphery of the radiation sensor(s) 80. The peripheral region 141 may provide I/O connections for the ASIC 130. For example, a plurality of wire bond connections 142 may extend between the peripheral region 141 of the ASIC 130 and the front side of the underlying carrier board 60, as is described and illustrated in the above-referenced U.S. patent application Ser. No. 18/158,695. The wire bond connections 142 between the carrier board 60 and the ASIC 130 may be in addition to, or may be in lieu of, electrical connections between the front side of the carrier board 60 and the back side of the ASIC 130 via TSVs 190 as described above.

In operation, the detector modules 200 including the radiation detector units 210 are exposed to ionizing radiation (e.g., X-rays). Exposure to high levels of radiation may cause permanent changes to semiconductor materials and/or to semiconductor device structures. In the context of X-ray imaging applications, such as photon counting computed tomography (PCCT) systems, direct conversion semiconductor detector materials such as CZT and CdTe are generally not strongly affected by exposure to the X-ray energies and fluxes typically encountered.

A more significant concern is X-ray radiation causing damage to the ASIC 130. The ASIC 130 typically includes metal oxide semiconductor field-effect transistors (MOSFETs) formed on and/or in a semiconductor (e.g., silicon) substrate. Certain parts of the MOSFET structures, including the gate insulators (e.g., silicon dioxide), are sensitive to ionizing radiation. When an ionizing particle goes through a MOS transistor, electron-hole pairs are generated. Within the gate of the transistor (e.g., polysilicon) and within in the semiconductor substrate that includes the active and channel regions of the transistor, these electron-hole pairs typically disappear quickly since these are materials have low resistivity. However, within insulating (e.g., oxide) materials of the transistor structure, which may include the gate insulator layer, gate sidewall spacer(s), etc., electrons and holes have different behaviors, as their mobilities differ by five to twelve orders of magnitude. A fraction of the radiation-induced electron-hole pairs will recombine immediately after being created. The electron-hole pairs which do not recombine may become separated in the insulating (i.e., oxide) material by the electric field. For example, in the case of a positive bias applied to the gate, the electrons drift to the gate in a very short time (order of picoseconds) whereas the holes move more slowly towards the SiO₂—Si interface. Close to the interface, but still within in the oxide, some of the holes may be trapped, resulting in a fixed positive charge in the oxide. This may cause, for example, a shift in the threshold voltage of the transistor. Ionizing radiation can also result in an increase in interface traps at the SiO₂—Si interface, which may, for example, degrade carrier mobility and increase leakage currents in the MOSFETs. The generation, transport, and trapping of holes in the oxide determines the amount of radiation damage to the ASIC 130 and is specific to the given CMOS processes used to fabricate the ASIC 130. Techniques have been developed to harden CMOS circuits against the effects of radiation damage (i.e., “Rad-Hard” processes). However, these techniques are much more expensive than conventional fabrication processes and can significantly increase the cost of manufacturing the ASIC 130. Thus, most commercially available ASIC chips used in detector read-out circuitry are not radiation hardened and remain highly susceptible to radiation-induced damage.

In a radiation detector unit 210, such as shown in FIG. 3A-3C, the ASIC 130 is at least partially shielded from the incoming X-ray photons by the radiation sensor 80. Direct conversion semiconductor detector materials like CZT are relatively X-ray absorbent and attenuate much of the incident photons before they reach the ASIC 130. The amount of X-ray attenuation is, in part, a function of the thickness of the sensor material. A typical thickness of the sensor material for a high-flux X-ray detector may be between about 1.5 mm and about 2.5 mm, such as ~2 mm. A 2 mm thick CZT sensor will typically absorb most X-ray photons, including nearly all lower energy X-ray photons (e.g., <60 keV). However, the shielding is not perfect and the photons that do make it through the sensor material and impinge on the ASIC 130 tend to be higher energy photons that produce the greatest amount of radiation damage.

Assuming, for example, an X-ray source with a 120 kVpp bias operating at a high flux rate typical of PCCT systems, the vast majority (e.g., >99%) of the photons will be absorbed by a 2 mm thick CZT radiation sensor 80. However, even with such a high attenuation rate, the flux rate of X-ray photons impinging on the ASIC 130 may still exceed 10⁶ Cps/mm². Assuming the average energy of the photons absorbed by the ASIC 130 to be 60 keV, the photon flux on the ASIC 130 can be translated to dose per second (i.e., energy per kg weight). At high flux rates, the dose absorbed by the ASIC 130 can be estimated to be ~0.03 Gy/s. If one assumes a cumulative dose of 1 kGy will result in permanent damage to the ASIC 130, the ASIC 130 only needs to be exposed to these high flux conditions for ~10 hours before suffering irreversible radiation damage.

If one assumes an average CT scan time of 10 seconds with 10% of this time being in high-flux regime, 10 hours translates into 36,000 scans. Assuming 18 scans per day, it means 2,000 days of scanner operating time, or about 6 years. For longer scans (some scans may be up to 1 minute or longer) this number decreases. Thus, the useful lifetimes of the ASICs 130 used in the read-out circuitry of PCCT systems may be relatively short.

This problem of radiation damage to the ASICs 130 may also be exacerbated based on the geometry of the radiation detector units 210 containing the ASICs 130. In the case of a radiation detector unit 210 including an interposer 40 as shown in FIG. 3A, the ASIC 130 may have a smaller horizontal cross-section area than the radiation sensor(s) 80 and thus may not extend to the peripheral edges of the radiation detector unit 210. Such a design may help to reduce total X-ray exposure by the ASIC 130 because the ASIC 130 is not exposed to scattered radiation around the periphery of the radiation detector unit 210. The presence of the interposer 40 between the sensor(s) 80 and the ASIC 130 may also provide some additional X-ray shielding.

In the case of a “direct attach” radiation detector unit 210 as shown in FIG. 3B, however, the ASIC 130 has a larger area that extends to the edges of the radiation detector unit 210. The ASIC 130 may thus be exposed to a large amount of scattered radiation along the edges of the ASIC 130 which may increase the rate of damage to the ASIC 130. The design of the radiation detector unit 210 shown in FIG. 3C includes the peripheral region 141 of the ASIC 130 that is not shielded by the radiation sensor(s) 80 and may include additional specialized shielding.

The above-described estimates and calculations of ASIC 130 radiation damage also have fairly large error bar (e.g., 3x), so the actual time to failure for the ASICs 130 may be highly variable. It is estimated that the time to failure for the ASICs 130 can be anywhere between about 1 year and about 20 years.

In an X-ray detector array 300 such as shown in FIGS. 2A and 2B, repair and/or replacement of many individual components of the array 300, such as the ASICs 130, may not be possible or may be cost prohibitive. The detector modules 200 and radiation detector units 210 of the array 300 form tightly integrated subsystems making field repairs of individual parts of these components impractical. Thus, repairs are often by necessity made at the modular level (i.e., by replacing defective detector modules 200 with new/refurbished detector modules 200) or at the sub-modular level (i.e., by replacing defective radiation detector units 210 of a module 200 with new/refurbished radiation detector units 210). From the perspective of an original equipment manufacturer (OEM), being able to accurately predict ahead of time when and how the various components of the detector array 300 will fail, and how many replacement units (e.g., detector modules 200 and/or radiation detector units 210) will be needed at different times, is beneficial for providing effective customer service. Simply waiting until after a failure mode has been detected by the customer (such as during a daily quality control (QC) scan) before replacing failed components is not an effective customer service strategy.

In the case of the detector read-out ASICs 130, it is known that these components will eventually fail due to radiation-induced damage, but as discussed above, there is a wide variance as to when these failures will occur. It would therefore be desirable to have a way of monitoring the amount of radiation damage experienced by each ASIC 130 in order to accurately predict ahead of time when the ASICs 130 (or the detector modules 200 or radiation detector units 210 containing such ASICs 130) will need to be replaced.

Various embodiments include methods and systems for monitoring radiation-induced aging of radiation detectors, and specifically for monitoring the radiation-induced aging of the ASICs 130 used in the read-out circuitry of the radiation detectors. In various embodiments, an output reference signal that is dependent on the threshold voltages of transistors within the ASICs 130 may be periodically measured. The measured output reference signals may be analyzed to determine when individual ASICs 130 of the radiation detector need to be replaced due to excessive radiation damage. In some embodiments, the output reference signal may be a direct current (DC) voltage signal that is generated by a bandgap reference circuit of the ASIC 130.

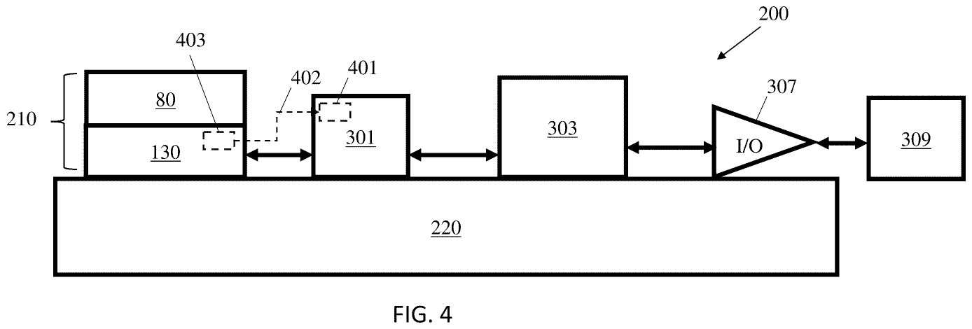

FIG. 4 is a system block diagram schematically illustrating a detector module 220 according to various embodiments of the present disclosure. The detector module 220 includes at least one above-described radiation detector unit 210 including at least one pixelated radiation sensor 80 and at least one ASIC 130. Each ASIC 130 may be configured to generate a stream of digitized X-ray count data representing photon detection events occurring within the pixelated radiation sensor(s) 80. The radiation detector unit 210 is illustrated in simplified form in FIG. 4, although it will be understood that the radiation detector unit 210 may include additional components, such as the above-described interposer 40, the above-described carrier board 60, and the like.

The detector module 200 in FIG. 4 further includes a local processing unit 301 and an associated memory 303. The detector module 200 may additionally include input/output (I/O) circuitry 307 that enables communication with one or more external components 309.

The local processing unit 301 may include, for example, a programmable logic core on a field programmable gate array (FPGA), a fixed processing core that may reside in a FPGA System-on-Chip (SoC) component, and/or as a separately packaged micro-controller component. Other suitable processing devices may be used for the local processing unit 301. In some embodiments, the local processing unit 301 may be located on the above-described module circuit board 220 of the detector module 200, although in other embodiments, the local processing unit 301 may be in other locations, such as on the above-described carrier board(s) 60 and/or implemented using one or more of the ASICs 130 of the detector module 220. In some embodiments, the detector module 200 may include more than one processor device (e.g., FPGA), where different processor devices may be configured to perform different functions and/or may be associated with different radiation detector units 210 or different sets of radiation detector units 210 of the detector module 200. The different processor devices may collectively form the local processing unit 301 for the detector module 200.

The memory 303 of the detector module 200 may include at least one suitable non-volatile or volatile memory 303. The memory 303 may include, for example, static random-access memory (SRAM), dynamic random-access memory (DRAM), electrically erasable programmable read-only memory (EEPROM), Flash memory, and/or any other type of volatile or non-volatile memory. In some embodiments, the memory 303 may be used to temporarily store the digitized X-ray count data before the data is output to an external component, such as a downstream aggregation point on the detector array 300 and/or an external computing device (e.g., the computing device 160 in FIG. 1B). In some embodiments, the memory 303 may be configured to store processing instructions (e.g., programs) for execution by the local processing unit 301 and/or to store additional data (e.g., configuration data, log data, etc.) that may be used by and/or generated by the local processing unit 301 and/or the ASIC(s) 130. In various embodiments, the local processing unit 301 may perform controller functions for controlling the operation of the detector module 200 and/or may perform processing functions on the stream of digitized X-ray count data prior to the data being transmitted from the detector module 220. In various embodiments described in further detail below, the local processing unit 301 may also be configured to perform radiation damage monitoring of the ASICs 130 of the detector module 220.

Referring again to FIG. 4, in some embodiments, the local processing unit 301 may include a monitoring component 401 that may be used to monitor radiation-induced aging of each of the ASICs 130 of the detector module 200. The monitoring component 401 may be configured to measure a reference signal (indicated by dashed line 402 in FIG. 4) from each of the ASICs 130 of the detector module 200 and to store a value associated with the reference signal 402 within the memory 303 of the detector module 200. In some embodiments, the reference signal 402 may be a DC voltage signal and the value stored in the memory 303 may represent the magnitude of the DC voltage signal. In various embodiments, the magnitude of the DC voltage signal may be dependent on the threshold voltage (V_{TH}) of transistors (e.g., MOS transistors) in the ASIC 130.

As discussed above, the transistors of the ASIC 130 may be susceptible to radiation damage from incident X-rays, particularly in the insulating materials (e.g., oxides) of the transistor structures. This damage may result in changes in the threshold voltages (V_{TH}) of transistors over time. In various embodiments, the reference signal 402 may be used to measure changes in the threshold voltages of transistors in the ASIC 130 as a proxy to determine the amount of radiation damage suffered by the ASIC 130.

In some embodiments, each of the ASICs 130 may include a monitoring circuit 403 that may be configured to generate the reference signal 402. In some embodiments, the monitoring circuit 403 may include a bandgap reference circuit. Bandgap reference circuits are used in many integrated circuit (IC) dies to produce a stable DC output reference voltage that is not sensitive to variations in the temperature or power supply (e.g., V_{dd}) of the die. This reference voltage may be distributed to other circuits of the die, and may be used, for example, for establishing comparator thresholds among other functions. Bandgap reference circuits typically include a plurality of MOSFETs which, as discussed above, are susceptible to damage from X-ray radiation, including changes in threshold voltages of the MOSFETs. These radiation-induced changes in the threshold voltages of the MOSFETS cause the output reference voltage of the bandgap reference circuit to decrease over time.

Accordingly, each of the ASICs 130 of the detector module 200 may include a bandgap reference circuit that is used as a monitoring circuit 403, where the output voltage of the bandgap reference circuit may be read by the monitoring component 401 and the stored in memory 303. Decreases in the output voltage of the bandgap reference circuit over time may indicate that MOSFETs of the bandgap reference circuit have suffered radiation damage, which may indicate the ASIC 130 as a whole has been damaged by X-ray radiation exposure.

In some embodiments, the monitoring component 401 may be configured to read and store the value of the reference signal 402 from some or all of the ASICs 130 of the detector module 200 on a periodic basis, which may include prior to or following each imaging scan. The value of the reference signal 402 may be stored locally in the memory 303 of the detector module 200 as shown in FIG. 4, or may be stored in a memory located externally to the detector module 200, such as in a central memory of the imaging system. In embodiments in which the reference signal values are stored locally in the memory 303 of the detector module 200, the monitoring component 401 may also be configured to periodically transmit the stored reference signal values from the detector module 200 to an external entity 309, which may include for example, a central controller/computing device of the imaging system 100 (e.g., computing device 160 in FIG. 1B), a computer system of the user of the imaging system 100, and/or a computer system of the manufacturer/servicer of the imaging system 100. In some embodiments, the reference signal values from all of the ASICs 130 in all of the detector modules 200 of the detector array 300 may be transmitted together to a central entity 309 to enable analysis of the radiation-induced aging of the ASICs 130 of the detector array 300. This may be done, for example, on a periodic basis (e.g., daily) as part of a quality control (QC) protocol.

In some embodiments, the reference signal values may be analyzed to determine whether the reference signal values for any ASICs 130 are below a maintenance threshold value. The maintenance threshold value may be a pre-determined value that is determined empirically for a given ASIC 130 design. In some embodiments, the maintenance threshold may be based on accelerated radiation hardness testing performed on a representative sample of ASICs 130. This may be performed, for example, by the manufacturer of the ASICs 130, of the detector modules 200 and/or of the imaging system 100. In some embodiments, when the measured reference signal value for a particular ASIC 130 is determined to be below the maintenance threshold value, a maintenance process may be initiated to replace the ASIC 130 prior to its ultimate failure. Replacing the ASIC 130 may include, for example, replacing a detector structure that includes the damaged ASIC 130, such as an above-described radiation detector unit 210 and/or an above-described detector module 200.

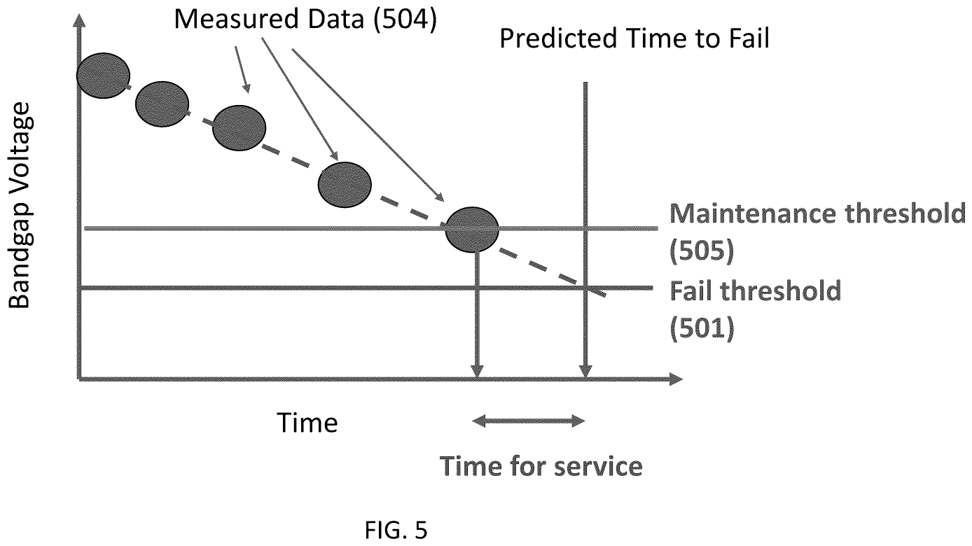

FIG. 5 is a plot schematically illustrating ASIC reference signal values as a function of time according to various embodiments of the present disclosure. Referring to FIG. 5, a representative sample of ASICs 130 may be subjected to radiation testing, such as accelerated radiation hardness testing, and their reference signal values (i.e., bandgap reference circuit DC output voltages) may be recorded over time. The relationship between the reference signal values and radiation exposure time may be plotted as indicated by the dashed line in FIG. 5. This relationship between the reference signal values and radiation exposure time may be used to determine the maintenance threshold 505 for the ASICs 130. As shown in FIG. 5, the measured reference signal values (indicated by dots 504 in FIG. 5) decrease with increased time of exposure to X-ray radiation. A fail threshold 501 may be defined as the reference signal value at the time in which the ASICs 130 have suffered sufficient radiation damage such that they are no longer considered functional and require immediate replacement. The maintenance threshold 505 may be defined as the reference signal value at a time preceding the predicted failure time of the AISCs 130 by a period sufficient to allow the maintenance process to be completed such that radiation-damaged ASICs 130 may be replaced before permanently failing in the field.

In some embodiments, maintenance threshold values 505 may be determined by the manufacturer for different types (e.g., models, designs, lot numbers, etc.) of the ASICs 130. The maintenance threshold 505 for the particular type of ASICs 130 used in a detector array 300 of an imaging system 100 may be stored in a memory of the imaging system 100, such as in a local memory 303 of the detector modules 200 as described above. A monitoring component 401 as described above may be configured to compare the measured reference signal values for the ASICs 130 with the stored maintenance threshold value 505. When measured reference signal values for ASICs 130 are determined to be below the maintenance threshold value 505, the monitoring component 401 may be configured to automatically initiate a maintenance process for the damaged ASICs 130. This may include, for example, providing an alert to the end-user of the imaging system 100 advising them to schedule a service appointment to replace the damaged ASIC 130 and/or notifying the manufacturer or servicer of the imaging system 100 that a service appointment to replace the damaged ASIC 130 is required. In various embodiments, the maintenance threshold value 505 may be updated as needed if there are changes in the design and/or manufacturing process of the radiation detector units 210 that may affect the time-to-failure of the ASICs 130 due to radiation exposure.

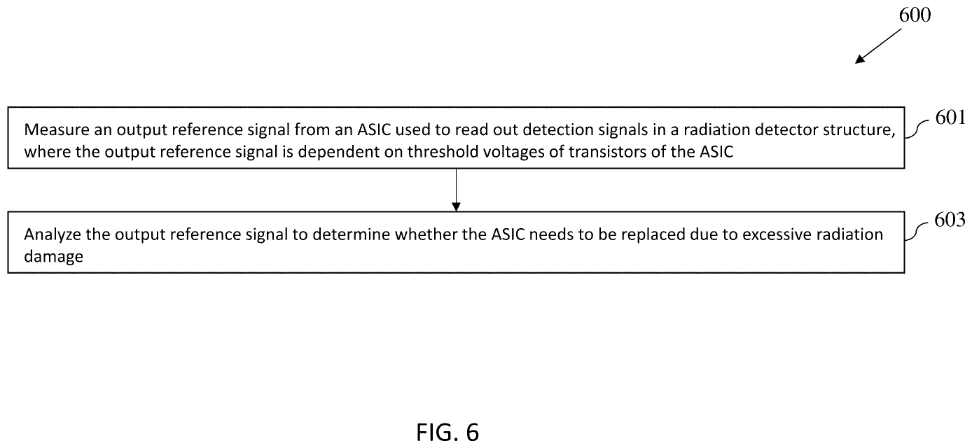

FIG. 6 is a flow diagram that illustrates a method 600 of monitoring radiation-induced aging of ASICs 130 used in the read-out circuitry of radiation detector structures 210, 200. Referring to FIG. 6, in step 601 of method 600, an output reference signal 402 from the ASIC 130 may be measured, where the output reference signal 402 is dependent on the threshold voltages of transistors within the ASIC 130. As discussed above, the output reference signal 402 may be a DC voltage signal that may be generated by the monitoring circuit 403 within the ASIC 130. In some embodiments, the monitoring circuit 403 may be a bandgap reference circuit including a plurality of MOSFET transistors.

In step 603 of method 600, the measured output reference signal 402 may be analyzed to determine whether the ASIC 130 needs to be replaced due to excessive radiation damage. In some embodiments, this may include comparing a value associated with the measured output reference signal 402 to a maintenance threshold value 505. The maintenance threshold value 505 may be a pre-determined value based on radiation hardness testing performed on identical or similar ASICs 130. The maintenance threshold value 505 may correspond to the value of the output refence signals 402 of the ASICs 130 at a time preceding the predicted failure time of the AISCs 130 by a period sufficient to enable the ASICs 130 to be replaced. Thus, ASICs 130 that have suffered radiation damage may be replaced before experiencing total failure.

The various embodiments of the present disclosure can be employed in various radiation detection systems including computed tomography (CT) imaging systems. Any direct conversion radiation sensors may be employed such as radiation sensors employing Si, Ge, GaAs, CdTe, CdZnTe, and/or other similar semiconductor materials.

The methods and systems for monitoring radiation-induced aging of ASICs described herein may be used for medical imaging, such as in Low-Flux applications in Nuclear Medicine (NM), whether by Single Photon Emission Computed Tomography (SPECT) or by Positron Emission Tomography (PET), or for radiation therapy, or as radiation detectors in High-Flux applications, such as in X-ray Computed Tomography (CT) for medical applications, other non-CT X-ray applications, such as X-ray fluoroscopy, angiography, mammography, etc., and for non-medical imaging applications, such as in baggage security scanning and industrial inspection applications.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

1. A method of monitoring radiation-induced aging of an application specific integrated circuit (ASIC) used in the read-out circuitry of a radiation detector structure, comprising:
measuring an output reference signal from the ASIC, wherein the output reference signal is dependent on threshold voltages of transistors within the ASIC; and
analyzing the measured output reference signal to determine whether the ASIC needs to be replaced due to excessive radiation damage.

2. The method of claim 1, wherein the output reference signal from the ASIC comprises a direct current (DC) voltage signal generated by a monitoring circuit of the ASIC.

3. The method of claim 2, wherein the monitoring circuit comprises a bandgap reference circuit comprising a plurality of metal oxide semiconductor field effect transistors (MOSFETs).

4. The method of claim 2, wherein the radiation detector structure forms part of a detector array of an X-ray imaging system.

5. The method of claim 4, wherein the detector array comprises a plurality of radiation detector structures, each radiation detector structure comprising at least one radiation sensor and at least one ASIC, and the method comprises measuring output reference signals from a plurality of ASICs of the detector array and analyzing the measured output reference signals to determine whether any of the ASICs need to be replaced due to excessive radiation damage.

6. The method of claim 5, further comprising storing the DC voltage values of the measured output reference signals in a memory of the imaging system for subsequent analysis of the measured output reference signals.

7. The method of claim 5, wherein the output reference signals from the plurality of ASICs of the detector array are measured before or after each imaging scan performed by the CT imaging system.

8. The method of claim 2, wherein analyzing the measured output reference signal comprises comparing the DC voltage value of the measured output reference signal to a maintenance threshold value.

9. The method of claim 8, wherein the ASIC is determined to require replacement when the DC voltage value of the measured output reference signal is below the maintenance threshold value.

10. The method of claim 9, wherein the maintenance threshold value comprises a pre-determined DC voltage value based on radiation hardness testing performed on identical or similar ASICs.

11. The method of claim 10, wherein the maintenance threshold value corresponds to the DC voltage value of the output refence signals of the ASICs at a time preceding the predicted failure time of the AISCs by a period sufficient to permit the ASICs to be replaced prior to failure.

12. A detector module, comprising:
a radiation sensor;
an application specific integrated circuit (ASIC) electrically coupled to the radiation sensor and comprising signal processing circuitry configured to generate detection signals in response to photon detection events occurring within the radiation sensor, the ASIC further comprising a monitoring circuit configured to generate an output reference signal that is dependent on threshold voltages of transistors within the ASIC; and
a monitoring component configured to measure the output reference signal from the monitoring circuit and to store a value associated with the measured output reference signal in a memory.

13. The detector module of claim 12, wherein the monitoring circuit of the ASIC comprises a bandgap reference circuit that generates a direct current (DC) voltage output reference signal, and the monitoring component is configured to store the magnitude of the DC voltage output reference signal in the memory.

14. The detector module of claim 13, further comprising a local processing unit, wherein the monitoring component is located in the local processing unit.

15. The detector module of claim 14, further comprising a local memory, wherein the monitoring component is configured to periodically measure the DC voltage output reference signal from the monitoring circuit of the ASIC and to store the magnitude of the measured DC voltage signals in the local memory.

16. The detector module of claim 15, wherein the detector module comprises a plurality of ASICs, each of the ASICs electrically coupled to one or more radiation sensors, wherein the monitoring component is configured to periodically measure the DC voltage output reference signal from the monitoring circuits of each of the ASICs and to store the magnitude of the measured DC voltage signals in the local memory.

17. The detector module of claim 16, wherein the monitoring component is configured to periodically transmit the magnitudes of the measured DC voltage signals stored in the local memory from the detector module to an external device.

18. The detector module of claim 15, wherein the monitoring component is configured to:
compare the DC voltage value of the measured output reference signal to a maintenance threshold value stored in the local memory; and
initiate a maintenance process to replace the ASIC when the DC voltage value of the measured output reference signal is below the maintenance threshold value.

19. The detector module of claim 12, wherein the radiation sensor comprises:
a direct conversion sensor material;
a cathode electrode located over a first side of the direct conversion sensor material; and
a plurality of anode electrodes located over a second side of the direct conversion sensor material, wherein each anode electrode defines a different pixel detector, and the ASIC is electrically coupled to the anode electrodes of the pixelated radiation sensor and configured to generate photon count data for multiple energy bins for each of the pixel detectors.

20. An X-ray imaging system, comprising:
a radiation source configured to emit an X-ray beam; and
a detector array comprising a detector module according to claim 12 that is configured to receive the X-ray beam from the radiation source through an intervening space configured to contain an object therein,
wherein the X-ray imaging system comprises a photon-counting computerized tomography (PCCT) imaging system comprising an image reconstruction system including a computer configured to run an automated image reconstruction algorithm on event detection signals generated by the pixel detectors of the detector array.
